(19) United States
(12) Patent Application Publication
(10) Pub. No.: US 2024/0014070 A1
(43) Pub. Date: Jan. 11, 2024

(54) CONTACT STRUCTURE AND METHOD FOR FABRICATING SAME

(71) Applicant: CHANGXIN MEMORY TECHNOLOGIES, INC., Hefei (CN)

(72) Inventors: Chuang SUN, Hefei (CN); Dandan HE, Hefei (CN)

(21) Appl. No.: 18/151,449

(22) Filed: Jan. 8, 2023

(30) Foreign Application Priority Data
Jul. 7, 2022 (CN) 202210795080.9

(51) Int. Cl. H01L 21/768; H01L 21/3213; H01L 21/02

(52) U.S. Cl. CPC H01L 21/76877; H01L 21/76805; H01L 21/76816; H01L 21/32133; H01L 21/02694; H01L 21/76897

(57) ABSTRACT

Embodiments provide a contact structure and a fabricating method. The method includes: forming an insulating dielectric layer on a substrate; forming a contact hole penetrating through the insulating dielectric layer, where the contact hole includes a first hole segment and a second hole segment communicating with each other, the first hole segment penetrates to the substrate, the second hole segment is positioned on a side of the first hole segment away from the substrate, the first hole segment has a first orthogonal projection on the substrate, the second hole segment has a second orthogonal projection on the substrate, and the second orthographic projection is positioned in the first orthographic projection; and forming a conductive plug in the contact hole.

### CROSS-REFERENCE TO RELATED APPLICATION

This application claims priority to Chinese Patent Application No. 202210795080.9, titled “CONTACT STRUCTURE AND METHOD FOR FABRICATING SAME” and filed to the State Patent Intellectual Property Office on Jul. 7, 2022, the entire contents of which are incorporated herein by reference.

### TECHNICAL FIELD

The present disclosure relates to the field of semiconductor technology, and more particularly, to a contact structure and a method for fabricating the same.

### BACKGROUND

With increasingly high integration level of a semiconductor, dimension of an integrated circuit gradually decreases. In general, a plurality of layers of interconnection lines are needed to meet interconnection requirements of components in the integrated circuit whose dimension is reduced. The interconnection lines may be connected via a conductive plug. When a depth of a contact structure having the conductive plug increases, a circulating current may be reduced, so a contact resistance of the conductive plug is of great importance.

However, as the dimension of the integrated circuit gradually decreases, dimension of a hole configured to arrange the conductive plug is also reduced accordingly, which makes it more and more difficult to reduce the contact resistance.

### SUMMARY

A main objective of the present disclosure is to provide a contact structure and a method for fabricating the same.

To achieve the above objective, according to an aspect of the present disclosure, there is provided a method for fabricating a contact structure, including following steps of: forming an insulating dielectric layer on a substrate; forming a contact hole penetrating through the insulating dielectric layer, where the contact hole includes a first hole segment and a second hole segment communicating with each other, the first hole segment penetrates to the substrate, the second hole segment is positioned on a side of the first hole segment away from the substrate, the first hole segment has a first orthogonal projection on the substrate, the second hole segment has a second orthogonal projection on the substrate, and the second orthographic projection is positioned in the first orthographic projection; and forming a conductive plug in the contact hole.

According to another aspect of the present disclosure, a contact structure is provided, including a conductive plug positioned on a substrate. The conductive plug includes: a first conductive segment and a second conductive segment connected to each other, and the second conductive segment is arranged on a side of the first conductive segment away from the substrate, where the conductive plug is shaped like an inverted wine cup, and a sectional dimension of the first conductive segment is greater than a sectional dimension of the second conductive segment.

### BRIEF DESCRIPTION OF THE DRAWINGS

The accompanying drawings constituting a part of the embodiments of the present disclosure are used to provide further understanding of the present disclosure, and the exemplary embodiments of the present disclosure and descriptions thereof serve to explain the present disclosure and do not impose an improper limitation on the present disclosure. In the drawings:

FIG. 1 shows a schematic cross-sectional structural diagram of a contact plug according to an embodiment of the present disclosure;

FIG. 2 shows a schematic cross-sectional structural diagram of forming an insulating dielectric layer in a method for fabricating a contact structure according to an embodiment of the present disclosure;

FIG. 3 shows a schematic cross-sectional structural diagram of forming a second hole segment in the insulating dielectric layer shown in FIG. 2;

FIG. 4 shows a schematic cross-sectional structural diagram of forming a contact hole in the insulating dielectric layer shown in FIG. 2;

FIG. 5 shows another schematic cross-sectional view of forming the contact hole in the insulating dielectric layer shown in FIG. 2;

FIG. 6 shows a schematic cross-sectional structural diagram of forming a semiconductor epitaxial layer in the contact hole shown in FIG. 4;

FIG. 7 shows a schematic cross-sectional structural diagram of forming a metal layer in the contact hole shown in FIG. 6;

FIG. 8 shows a schematic cross-sectional structural diagram of forming a metallic compound layer in the contact hole shown in FIG. 7;

FIG. 9 shows a schematic cross-sectional structural diagram of removing the unreacted metal layer in the contact hole shown in FIG. 8;

FIG. 10 shows a schematic cross-sectional structural diagram of forming a barrier layer in the contact hole shown in FIG. 9; and

FIG. 11 shows a schematic cross-sectional structural diagram of forming a seed layer in the contact hole shown in FIG. 10.

FIG. 12 shows a schematic cross-sectional structural diagram of forming a conductive plug in the contact hole shown in FIG. 11.

The above accompanying drawings include following reference numerals:

10: substrate; 20: first insulating layer; 30: second insulating layer; 40: second hole segment; 50: first hole segment; 60: contact hole; 70: semiconductor epitaxial layer; 80: metal layer; 90: heat-treated metal layer; 100: metallic compound layer; 110: barrier layer; 120: seed layer; 130: conductive plug; 140: first conductive segment; and 150: second conductive segment.

### DETAILED DESCRIPTION

It is to be noted that the embodiments of the present disclosure and the features in the embodiments may be combined with each other on a non-conflict basis. The present disclosure will be described below in detail with reference to the accompanying drawings and in combination with the embodiments.

To make a person skilled in the art better understand the solutions of the embodiments of the present disclosure, technical solutions in the embodiments of the present disclosure will be described clearly and completely below with reference to the accompanying drawings in the embodiments of the present disclosure. Apparently, the described embodiments are some but not all of the embodiments of the present disclosure. All other embodiments obtained by a person of ordinary skill in the art based on the embodiments of the present disclosure without creative efforts shall fall within the protection scope of the present disclosure.

It should be explained that in the specification, the claims and the foregoing accompanying drawings of the present disclosure, a term (such as a first or a second) is intended to separate between similar objects but is not intended to describe a sequence or precedence order. It is to be understood that data used like this may be interchangeable where appropriate, such that the embodiments of the present disclosure are described herein. Furthermore, terms such as “comprise”, “have” or other variants thereof are intended to cover a non-exclusive “comprise”, for example, processes, methods, systems, products or devices comprising a series of steps or units are not limited to these steps or units listed explicitly, but comprise other steps or units not listed explicitly, or other steps or units inherent to these processes, methods, systems, products or devices.

In some embodiments, due to the increasingly high integration level of semiconductors, dimensions of integrated circuits gradually decrease, and a dimension of a hole configured to arrange a conductive plug is also reduced accordingly, which makes it more and more difficult to reduce a resistance value of a contact resistance, resulting in higher contact resistance of the conductive plug formed in the integrated circuits.

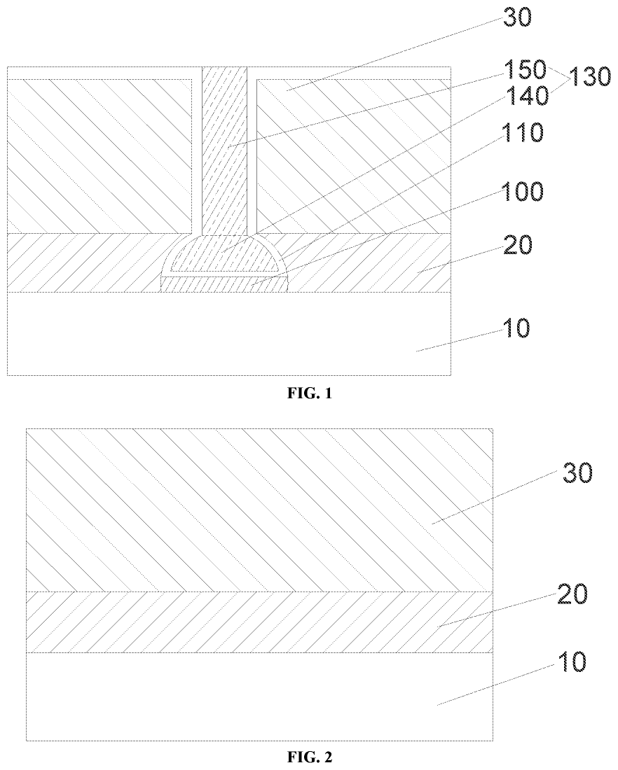

According to an embodiment of the present disclosure, a method for fabricating a contact structure is provided. The method includes: forming an insulating dielectric layer on a substrate 10; forming a contact hole 60 penetrating through the insulating dielectric layer, where the contact hole 60 includes a first hole segment 50 and a second hole segment 40 communicating with each other, the first hole segment 50 penetrates to the substrate 10, the second hole segment 40 is positioned on a side of the first hole segment 50 away from the substrate 10, the first hole segment 50 has a first orthogonal projection on the substrate 10, the second hole segment 40 has a second orthogonal projection on the substrate 10, and the second orthographic projection is positioned in the first orthographic projection; and forming a conductive plug 130 in the contact hole 60, as shown in FIG. 1.

In the above method, in the process of forming the conductive plug, the formed contact hole 60 penetrating through the insulating dielectric layer includes the first hole segment 50 and the second hole segment 40 communicating with each other, and the first orthographic projection and the second orthographic projection respectively corresponding to the first hole segment 50 and the second hole segment 40 have different dimensions. That is, the second orthographic projection is positioned in the first orthographic projection, such that the bottom of the contact hole can have the larger accommodating dimension than the upper part of the contact hole, and the conductive plug formed in the above contact hole 60 can have the larger area of contact with the substrate, thereby reducing the contact resistance of the conductive plug.

Exemplary embodiments of the method for fabricating the contact structure provided according to the present disclosure will be described in more detail below with reference to the accompanying drawings. These exemplary embodiments may, however, be embodied in many different forms and should not be construed as limited to the embodiments set forth herein. It should be understood that these embodiments are provided such that the present disclosure will be thorough and complete, and will fully convey the concept of these exemplary embodiments to those skilled in the art.

As shown in FIG. 2, the insulating dielectric layer is first formed on the substrate 10.

A material of the substrate 10 may be monocrystalline silicon (Si), monocrystalline germanium (Ge), silicon germanium (GeSi), silicon carbide (SiC), silicon-on-insulator (SOI), germanium-on-insulator (GOI), or other materials, e.g., III-V group compounds such as gallium arsenide.

In some embodiments, the insulating dielectric layer includes a first insulating layer 20 and a second insulating layer 30 that are sequentially stacked along a direction away from the substrate 10. By arranging the two insulating dielectric layers, a silicon wafer may be protected. The insulating dielectric layers may also serve as buffer dielectric layers, which is advantageous to better etching, thereby forming the conductive plug with higher integrity.

In some embodiments, after the first insulating layer 20 and the second insulating layer 30 as shown in FIG. 2 are formed, the second insulating layer 30 is subjected to a first step of etching to form the second hole segment 40 as shown in FIG. 3.

The second insulating layer 30 may be etched by means of dry etching or wet etching to form the second hole segment 40, where the second hole segment 40 is at least positioned in the second insulating layer 30. That is, the second hole segment 40 may be positioned in the second insulating layer 30, or may penetrate the second insulating layer 30, or may penetrate through the second insulating layer 30 into the first insulating layer 20.

For example, the above second hole segment 40 is of a vertical tubular structure. First a side surface of the second insulating layer 30 away from the substrate 10 is coated with a photoresist, then the photoresist is exposed by means of photoetching to form a mask layer, and next a region not covered by the mask layer is selectively etched by means of plasma etching to form the second hole segment 40.

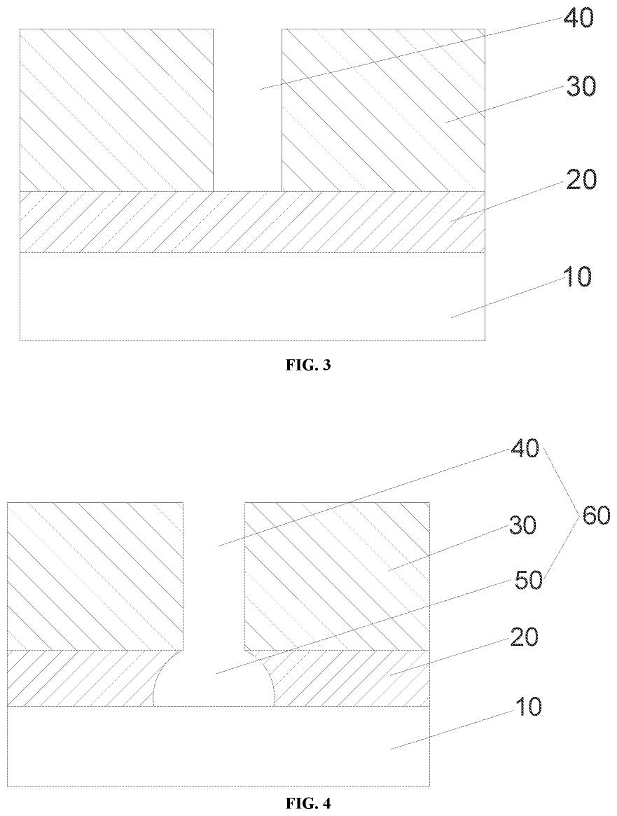

In some embodiments, after the second hole segment 40 penetrating through the second insulating layer 30 to the first insulating layer 20 is formed, the first insulating layer 20 continues to be etched on the basis of the second hole segment 40 to form the first hole segment communicating with the second hole segment 40, and the first hole segment 50 and the second hole segment 40 jointly constitute the contact hole 60, as shown in FIGS. 4 and 5.

In some embodiments, as shown in FIG. 4, the second hole segment 40 penetrates through the second insulating layer 30 to the surface of the first insulating layer 20 away from the substrate 10, and the first hole segment 50 communicates with the second hole segment 40, and penetrates through the first insulating layer 20 to the surface of the substrate 10.

The first insulating layer 20 may be etched by means of wet etching or dry etching to form the first hole segment 50.

In some embodiments, the first insulating layer 20 is etched by introducing the chlorine and/or fluorine group-containing gas into the reaction chamber for plasmas by means of plasma etching to form the first hole segment 50, as shown in FIG. 4, where the above chlorine and/or fluorine group-containing gas includes, but is not limited to, any one or more of chlorine, difluoromethane, sulfur hexafluoride, boron trichloride, and nitrogen trifluoride.

The above second hole segment 40 may be in the cylindrical shape, in the cuboid shape, or in any other shape which may communicate with the first hole segment 50 in a penetration manner, the above first hole segment 50 may be in the ellipsoidal shape, in the spherical shape, or in the combined shape of other shapes, the above first hole segment 50 and the second hole segment 40 jointly constitute the contact hole 60, and the dimension of the bottom of the contact hole 60 is greater than the dimension of the upper part of the contact hole 60.

In some embodiments, the above first hole segment 50 is positioned in the above first insulating layer 20, and the above second hole segment 40 is positioned in the above second insulating layer 30. That is, the contact hole 60 constituted by the first hole segment 50 and the second hole segment 40 penetrates through the second insulating layer 30 and the first insulating layer 20 to the surface of the substrate 10.

For example, as shown in FIG. 4, the second insulating layer 30 and the first insulating layer 20 are sequentially etched to form the contact hole 60 penetrating to the substrate 10, where the above second hole segment 40 is in the cylindrical shape, the above first hole segment 50 is in the irregular ellipsoidal shape, and the bottom of the first hole segment 50 is in contact with the surface of the substrate 10, thereby forming the structure of the contact hole 60 whose bottom is larger in dimension than the upper part.

In some other embodiments, as shown in FIG. 5, the second insulating layer 30, the first insulating layer 20, and the substrate 10 are sequentially etched to form the contact hole 60 penetrating into the substrate 10.

For example, as shown in FIG. 5, the above second hole segment 40 is in the cylindrical shape, the above first hole segment 50 is in the ellipsoidal shape, and part of the first hole segment 50 is positioned in substrate 10. The ellipsoidal long axis of the first hole segment 50 is greater than the diameter of the cylindrical bottom area of the second hole segment 40, thereby forming the contact hole 60 whose bottom is larger in dimension than the upper part.

The above second hole segment 40 is completely positioned in the second insulating layer 30, the first part of the above first hole segment 50 is positioned in the substrate 10, the second part of the first hole segment 50 is positioned in the first insulating layer 20, and the first part includes the arc-shaped bottom surface. The contact area of the arc-shaped bottom surface is larger, so the conductive contact is better.

The above contact hole 60 penetrating into the substrate 10 is formed by sequentially etching the second insulating layer 30, the first insulating layer 20, and the substrate 10, such that the contact hole 60 penetrates through the substrate 10, the first insulating layer 20, and the second insulating layer 30, thereby providing a corresponding region for forming the conductive plug having a connection effect, which can improve efficiency of the subsequent fabrication processes.

To form the contact hole 6 including the first hole segment 50 and the second hole segment 40, in some embodiments, the etching selectivity between the first insulating layer 20 and the second insulating layer 30 is controlled to form the contact hole 60 shaped like an inverted wine cup, as shown in FIG. 4 to FIG. 11.

In some embodiments, first in the process of etching the second insulating layer 30, a dimension of the second hole segment 40 is determined as a second dimension according to requirements of design processes, and etching is performed to form the second hole segment 40 with the second dimension. Next, a required etching dimension of the first hole segment 50 is determined according to a dimension ratio of the second hole segment 40 to the first hole segment 50 set by the contact structure, then etching is performed to obtain the first hole segment 50, and the dimension of the first hole segment 50 formed by etching is determined as a first dimension.

The etching selectivity for etching the above second hole segment 40 and the first hole segment 50 may be adjusted according to the actual process requirement. For example, when the etching diameter for etching the above second hole segment 40 is set to be the numerical value a, and the etching selectivity between the second hole segment 40 and the first hole segment 50 is determined to be 1:2, the obtained etching diameter for etching the above first hole segment 50 is the numerical value 2a.

The above first dimension and the second dimension may be correspondingly adjusted according to different requirements of a device to obtain the first hole segments 50 and the second hole segments 40 with different dimension ratios, thereby adapting to different device structures.

The above first dimension and the second dimension include the horizontal dimension and/or the vertical dimension and the dimensions, in different directions, determined according to different shapes of the first hole segment and the second hole segment.

In some embodiments, the first hole segment 50 and the second hole segment 40 constitute a structure of the contact hole 60 shaped like an inverted wine cup. That is, in the process of etching the insulating layers, first the second insulating layer 30 is etched to form the vertical tubular hole structure as the second hole segment 40, and then the first insulating layer 20 continues to be etched on the basis of the second hole segment 40 to form the first hole segment 50. In the process of etching the first hole segment 50, an etching region of the first insulating layer 20 that needs to be etched is first planned. In this embodiment, it is selected to etch along the direction where the second hole segment 40 extends to the substrate 10, and it is expanded outwards along an edge where the second hole segment 40 in the first insulating layer 20, to form the first hole segment 50 shaped like the inverted wine cup.

In some embodiments, in the direction parallel to the surface of the substrate 10, the ratio of the maximum sectional dimension of the first hole segment 50 to the maximum sectional dimension of the second hole segment 40 is greater than or equal to 2, and the dimension of the contact surface between the first hole segment 50 and the substrate 10 is greater than the dimension of the second hole segment 40, such that the conductive plug of the corresponding dimension is obtained, and the formed conductive plug can have the larger area of contact with the substrate, thereby reducing the contact resistance of the conductive plug.

In some embodiments, after the contact hole 60 is formed, a conductive plug is formed in the contact hole 60.

The conductive plug may be formed by means of a self-alignment process, or may be formed by means of chemical vapor deposition or physical vapor deposition, which is not limited in the present disclosure.

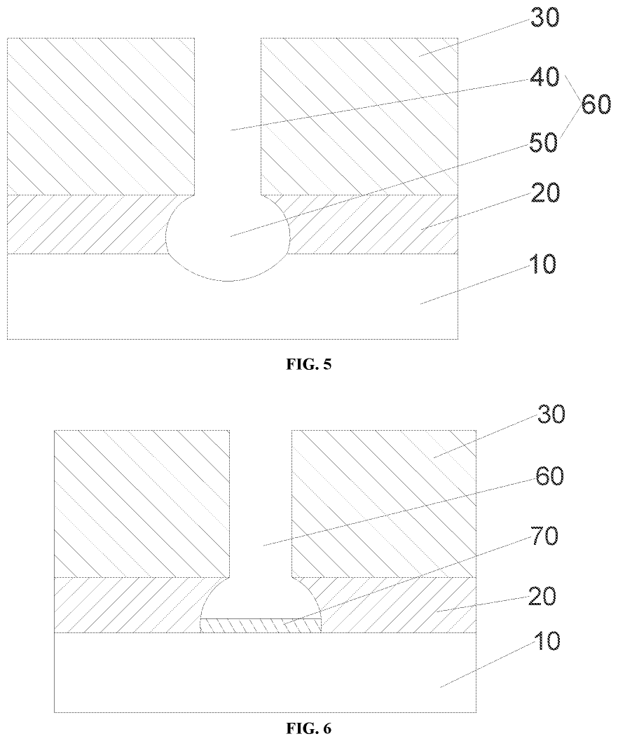

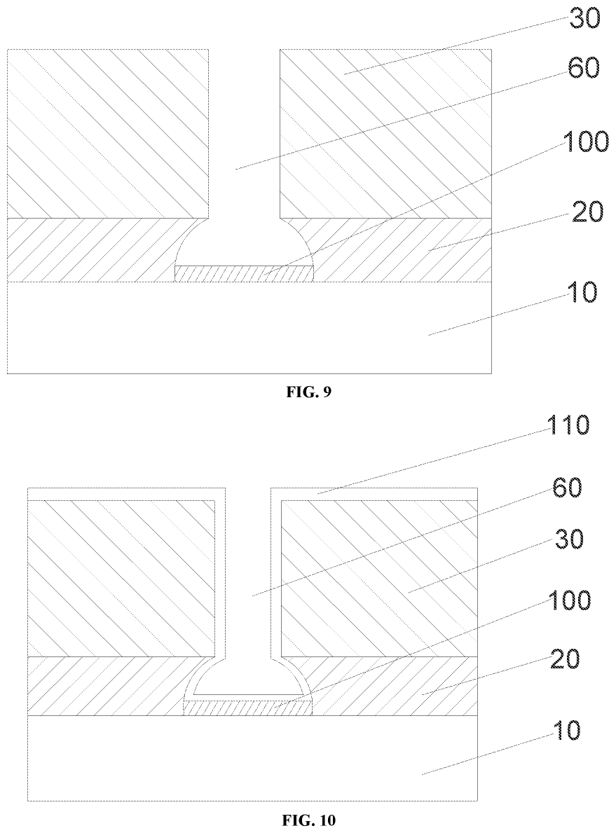

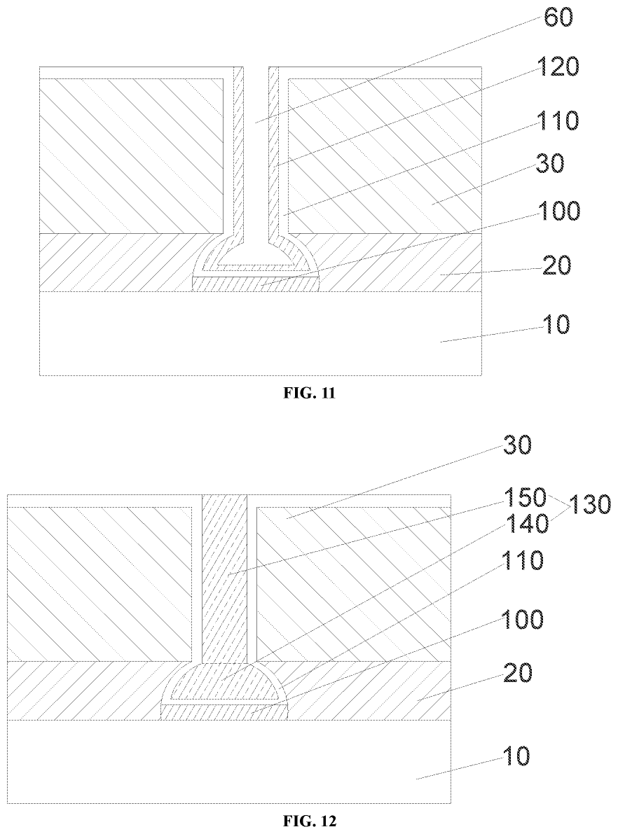

In some embodiments, as shown in FIGS. 6 to 11, the step of forming the conductive plug includes: forming a metallic compound layer 100 on a bottom surface of the contact hole 60, as shown in FIGS. 6 to 8; covering a barrier layer 110 on a hole wall of the contact hole 60 and on a surface of the metallic compound layer 100, as shown in FIG. 9 and FIG. 10; and forming a metal filling portion on a surface of the barrier layer 110, where a filling material positioned in the metal filling portion fills up the contact hole 60, as shown in FIG. 11 and FIG. 12.

The metallic compound layer 100 is formed on the bottom surface of the contact hole 60, where the electrical conductivity of the above metallic compound is lower than the electrical conductivity of the metal, and the metallic compound may be the compound of cobalt, the compound of titanium, or the compound of nickel. The barrier layer 110 includes a nitrided metal layer, and the nitrided metal layer may be selected from one of the group comprising a titanium nitride layer, a tungsten nitride layer, and a tantalum nitride layer. The filling material of the above metal filling portion may include titanium, tungsten, nickel, or tantalum, etc.

In some embodiments, the step of forming the metallic compound layer 100 includes: covering a metal layer 80 on the hole wall and the bottom surface of the contact hole and annealing the substrate 10 covered with the metal layer 80, such that the metal layer reacts with the substrate 10 to form the metallic compound layer 100.

Metals of the metal layer 80 may include any one or more of cobalt, iridium, nickel, molybdenum, and ruthenium.

In some embodiments, the metal layer 80 is a cobalt layer, and cobalt has higher heat resistance and toughness, such that a service life of the conductive plug can be prolonged.

In some embodiments, the cobalt layer is obtained by means of physical vapor deposition, where the process of obtaining the cobalt layer by means of physical vapor deposition is simple, has no pollution to the environment, consumes few materials, and has strong adhesion to the substrate.

In some embodiments, the target material is bombarded with ionized inert gas ions under combined action of the voltage and the magnetic field in the vacuum environment by means of magnetron sputtering, such that the target material is ejected in the form of ions, atoms, or molecules and is deposited on the silicon substrate 10 to form the thin film. The cobalt layer formed by means of electroplating is relatively uniform, and the damage of the substrate 10 due to wear and processing errors is repaired to a certain extent.

In some embodiments, the above substrate 10 covered with the cobalt layer is annealed to form the metallic compound layer 100, thereby forming the compound layer with lower electrical conductivity. In addition, the compound of the cobalt further has relatively strong adhesion, which can improve the adhesion to the substrate 10.

In some embodiments, after the substrate is covered with the cobalt layer, the compound layer of the cobalt is formed by means of low-temperature annealing, where the temperature range is controlled to be 600-900° C. At this temperature, the internal structure of the cobalt can reach or approach the equilibrium state, thereby obtaining the compound of the cobalt with good process performance and service performance. For example, at this temperature, CoSi₂ with lower resistance can be formed.

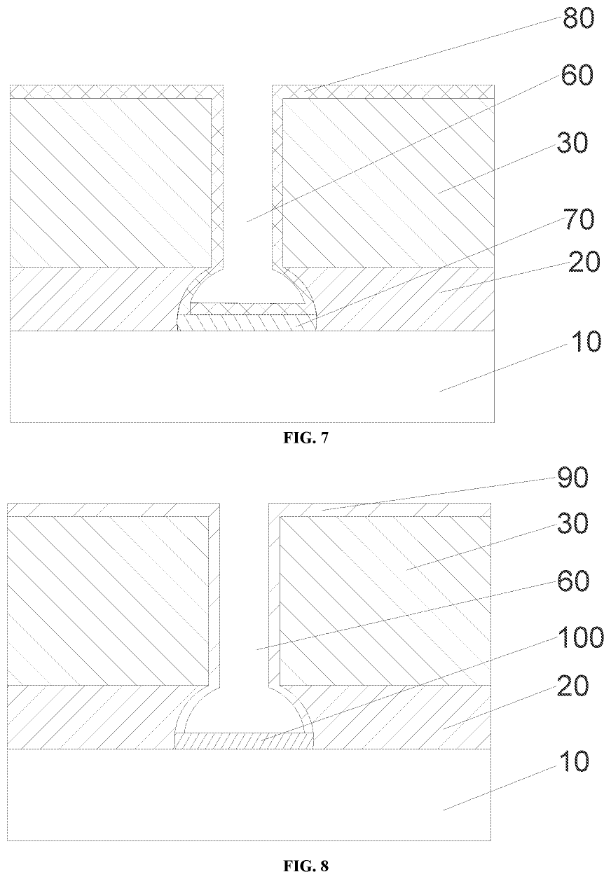

In some embodiments, the forming the metallic compound layer 100 includes: forming a semiconductor epitaxial layer 70 on the bottom surface of the contact hole 60, as shown in FIG. 6; forming, in the contact hole 60, the metal layer 80 at least covering the semiconductor epitaxial layer 70, as shown in FIG. 7; and annealing the semiconductor epitaxial layer 70 covered with the metal layer 80, such that the metal layer 80 reacts with the semiconductor epitaxial layer 70 to form the metallic compound layer 100, as shown in FIG. 8.

As shown in FIG. 6, the above semiconductor epitaxial layer 70 may be epitaxy of silicon. A high-quality silicon layer is epitaxially grown on the bottom surface of the contact hole 60, and then silicon reacts with metal to form the metallic compound layer 100 by means of annealing. That is, the above metallic compound layer 100 is a metal silicide layer. The above metal layer 80 is softened by means of annealing to obtain a heat-treated metal layer 90, as shown in FIG. 8.

Because the contact hole 60 is shaped like the inverted wine cup, the cross-sectional diameter of a bottom end of the contact hole 60 is smaller than a middle of the first hole segment 50. The semiconductor epitaxial layer 70 formed by means of epitaxial growth can increase the area of contact with the conductive plug 130. In another aspect, the metallic compound layer 100 generated by means of reaction between the semiconductor epitaxial layer 70 formed by means of epitaxial growth and the metal layer 80 makes contact between the conductive plug 130 and an interface of the substrate 10 become better, such that the contact resistance can be greatly reduced.

In some embodiments, the thickness of the semiconductor epitaxial layer 70 is nm, and the thickness of the metal layer 80 is 5-30 nm.

By rationally setting the thickness range of the semiconductor epitaxial layer 70 and the thickness range of the metal layer 80, the silicon of the semiconductor epitaxial layer reacts with the metal of the metal layer 80 to form the metal silicide with a certain thickness to adjust the contact resistance of the contact structure, thereby obtaining the contact structure adapted to different devices.

In some embodiments, after the metallic compound layer 100 is formed, metal that does not react with silicon after the annealing, i.e., the heat-treated metal layer 90, in the above contact hole 60 is selectively removed, as shown in FIG. 9. Next, manufacture procedures for titanium are performed on the bottom and the side wall of the contact hole 60 after the heat-treated metal layer 90 is removed, to form the barrier layer 110. The barrier layer 110 covers the hole wall of the contact hole 60 and the metallic compound layer 100, as shown in FIG. 10.

In some embodiments, the step of forming the metal filling portion includes: covering a metal material on the surface of the barrier layer 110 to form a seed layer 120, as shown in FIG. 11; and filling conductive metal in the contact hole 60 by means of an electroplating process to form the conductive plug 130, as shown in FIG. 12. By forming the seed layer 120 such that the seed layer 120 covers the bottom surface and the side wall surface of the contact hole 60, current-carrying capacity during the electroplating process is improved.

In the above embodiment, a metal material for forming the seed layer 120 may include tungsten.

In the above embodiment, the surface of the barrier layer 110 may be covered with tungsten by means of chemical vapor deposition to form a tungsten thin film, and the tungsten thin film is used as the seed layer 120 for metal filling.

In some embodiments, after the seed layer 120 is formed, the contact hole 60 is filled up from bottom to top by means of the electroplating process. Because the above contact hole 60 is shaped like the inverted wine cup, when the contact hole 60 is filled up with metal by means of conventional chemical vapor deposition (CVD), it may lead to a phenomenon that a void may be easily formed at a larger position in the middle of the conductive plug, which may have a negative effect on an overall resistance of the conductive plug. Therefore, in this embodiment, the contact hole 60 is filled up from bottom to top by means of electroplating, thereby avoiding the phenomenon that the void may be easily formed in the contact hole 60, which is advantageous to forming the high-quality conductive plug.

In some embodiments, the thickness of the above seed layer 120 is 2-20 nm. When the seed layer 120 is thicker, it may lead to a smaller opening of the contact hole 60, which increases the difficulty of electroplating. However, when the seed layer 120 is thinner, it may lead to fewer coverage of the side wall, which reduces the current-carrying capacity, and defects may also be formed during electroplating. Therefore, the thickness of the seed layer 120 is set to be 2-20 nm, to ensure that the electroplating process is effectively performed.

According to another embodiment of the present disclosure, a contact structure is provided, including a conductive plug 130 on the substrate 10. The conductive plug 130 includes a first conductive segment 140 and a second conductive segment 150 connected to each other, where the second conductive segment 150 is arranged on a side of the first conductive segment 140 away from the substrate 10. The conductive plug 130 is shaped like an inverted wine cup, and a sectional dimension of the first conductive segment 140 is greater than that of the second conductive segment 150, as shown in FIG. 12.

The conductive plug may be formed by means of a self-alignment process, or may be formed by means of chemical vapor deposition or physical vapor deposition.

In some embodiments, the first conductive segment 140 is positioned in the substrate 10 and the first insulating layer 20. That is, the first conductive segment 140 is partially positioned in the substrate 10 and partially positioned in the first insulating layer 20. The second conductive segment 150 is positioned in the second insulating layer 30.

In some embodiments, the first conductive segment 140 is positioned in the first insulating layer 20, and the second conductive segment 150 is positioned in the second insulating layer 30.

In some embodiments, in a direction parallel to a surface of the substrate 10, a ratio of a maximum sectional dimension of the first conductive segment 140 to a maximum sectional dimension of the second conductive segment 150 is greater than or equal to 2.

The above conductive plug 130 may be adjusted by means of corresponding processes according to different requirements of the device to obtain the first conductive segments 140 and the second conductive segments 150 with different dimension ratios, thereby adapting to different device structures.

For example, when the maximum sectional dimension of the above second conductive segment 150 is the numerical value a, and the ratio of the maximum sectional dimension of the first conductive segment 140 to the maximum sectional dimension of the second conductive segment 150 is determined to be 2, the maximum sectional dimension of the above first conductive segment 140 is the numerical value 2a.

In some embodiments, the conductive plug 130 further includes: a metallic compound layer 100 disposed between the substrate 10 and the first conductive segment 140.

The above metallic compound layer 100 may have better adhesion to the substrate 10, and the electrical conductivity of the metal compound is lower than the electrical conductivity of the corresponding metal, such that the resistance of the conductive plug 130 can be reduced.

In some embodiments, the contact structure further includes: a barrier layer 110 at least covering a periphery of the conductive plug 130.

The above barrier layer 110 may be fabricated by means of chemical vapor deposition (CVD) or physical vapor deposition (PVD), and the barrier layer 110 may be selected from either a titanium layer or a titanium nitride layer, and serves as a connection layer or an adhesive to assist in close combination between the filled metal and the substrate 10, thereby preventing separation of the filled metal from the substrate 10. Moreover, the barrier layer 110 can prevent the conductive material of the conductive plug 130 from diffusing to the metallic compound layer 100 and the substrate 10, thereby avoiding having a negative effect on the contact resistance.

The above conductive plug 130 includes, but is not limited to, a conductive tungsten plug, and may also be other type of conductive metal, which is not limited in the present disclosure.

According to yet another embodiment of the present disclosure, there is provided a semiconductor device having the above contact structure. The device includes a substrate and the contact structure, and a contact hole is formed in a source region and/or a drain region of the substrate, where the contact structure is formed in the contact hole. In some embodiments, the semiconductor device is, for example, a field effect transistor.

The above contact structure and the method for fabricating the same in the present disclosure may be further described in combination with the embodiments below.

### Embodiment 1

A silicon nitride layer is grown on the silicon substrate 10 to serve as the first insulating layer 20, and then a silicon oxide layer is grown to serve as the second insulating layer 30.

On the cross section parallel to the substrate 10, the second insulating layer 30 and the first insulating layer 20 (i.e., the silicon oxide layer and the silicon nitride layer) are sequentially etched by means of an etching selectivity where the ratio of the maximum sectional dimension of the first conductive segment 50 to the maximum sectional dimension of the second conductive segment 40 is equal to 2, to form the contact hole 60 shaped like the inverted wine cup. The bottom of the contact hole 60 is a plane, as shown in FIG. 4, where a height ratio of the bottom of the contact hole 60 to the wine cup is 2:1.

A high-quality silicon layer having a thickness of 10-20 nm is grown on the bottom of the contact hole 60 by means of epitaxial growth.

A cobalt thin film having a thickness of 5-30 nm is deposited on the epitaxially grown silicon and the side wall of the contact hole 60 by means of sputtering of physical vapor deposition.

The above cobalt thin film formed by means of deposition is annealed at a low temperature of 600-900° C. to form CoSi₂ with lower resistance on the bottom of the contact hole 60.

The cobalt thin film unreacted after annealing is selectively removed.

The manufacture procedures for titanium are performed on the bottom of the contact hole 60 and on the side wall of the contact hole 60 by means of chemical vapor deposition to form the barrier layer 110, where the thickness of the above titanium is 2-20 nm.

The tungsten is deposited on the bottom surface and the side wall surface of the contact hole 60 by means of chemical vapor deposition on the basis of the barrier layer 110 to obtain a layer of tungsten thin film having a thickness of 2-20 nm, where the tungsten thin film serves as the seed layer 120.

The above contact hole 60 is filled up with the tungsten from bottom to top by means of the electroplating process to form the conductive tungsten plug.

### Embodiment 2

A silicon nitride layer is grown on the silicon substrate 10 to serve as the first insulating layer 20, and then a silicon oxide layer is grown to serve as the second insulating layer 30.

On the cross section parallel to the substrate 10, the second insulating layer 30 and the first insulating layer 20 (i.e., the silicon oxide layer and the silicon nitride layer) and the substrate 10 are sequentially etched by means of an etching selectivity where the ratio of the maximum sectional dimension of the first conductive segment 50 to the maximum sectional dimension of the second conductive segment 40 is equal to 2, to form the contact hole 60 shaped like the inverted wine cup. The bottom of the contact hole 60 is an arc-shaped bottom surface, as shown in FIG. 5, where a height ratio of the bottom of the contact hole 60 to the wine cup is 2:1.

A high-quality silicon layer is grown on the arc-shaped bottom surface at the bottom of the contact hole 60 by means of epitaxial growth, the thickness of the silicon layer is 10-20 nm, and a cross-sectional shape of the epitaxially grown silicon layer is also arc-shaped.

The cobalt thin film having a thickness of 5-30 nm is deposited on the epitaxially grown silicon and the side wall of the contact hole 60 by means of sputtering of physical vapor deposition.

The above cobalt thin film formed by means of deposition is annealed at a low temperature of 600-900° C. to form an arc-shaped CoSi₂ with lower resistance on the bottom of the contact hole 60, where the arc-shaped bottom surface may have a larger contact area and a better conductive contact.

The cobalt thin film unreacted after annealing is selectively removed.

The manufacture procedures for titanium are performed on the bottom surface of the contact hole 60 and on the side wall surface of the contact hole 60 by means of chemical vapor deposition to form the barrier layer 110, where the thickness of the above titanium is 2-20 nm.

The tungsten is deposited on the bottom and the side wall of the contact hole 60 by means of chemical vapor deposition on the basis of the barrier layer 110 to obtain a layer of tungsten thin film having a thickness of 2-20 nm, where the tungsten thin film serves as the seed layer 120.

The above contact hole 60 is filled up with the tungsten from bottom to top by means of the electroplating process to form the conductive tungsten plug.

As can be seen from the above description, the embodiments of the present disclosure achieve the following technical effects.

The first hole segment and the second hole segment communicating with each other are formed, and the first hole segment penetrates to the substrate, where the second hole segment is positioned on a side of the first hole segment away from the substrate, the first hole segment has a first orthographic projection on the substrate, the second hole segment has a second orthographic projection on the substrate, and the second orthographic projection is positioned in the first orthographic projection. In this way, a bottom of the contact hole can have a larger accommodating dimension than an upper part of the contact hole, such that the conductive plug formed in the contact hole can have a larger area of contact with the substrate, thereby reducing a contact resistance of the conductive plug.

The above are merely some embodiments of the present disclosure and are not intended to limit the present disclosure. To those skilled in the art, the present disclosure may have various modifications and changes. All modifications, equivalent substitutions and improvements made within the spirit and principle of the present application shall fall within the protection scope of the present disclosure.

What is claimed is:

1. A method for fabricating a contact structure, comprising:
forming an insulating dielectric layer on a substrate;
forming a contact hole penetrating through the insulating dielectric layer, the contact hole comprising a first hole segment and a second hole segment communicating with each other, the first hole segment penetrating to the substrate, the second hole segment being positioned on a side of the first hole segment away from the substrate, the first hole segment having a first orthogonal projection on the substrate, the second hole segment having a second orthogonal projection on the substrate, the second orthographic projection being positioned in the first orthographic projection; and
forming a conductive plug in the contact hole.

2. The method according to claim 1, wherein the insulating dielectric layer comprises a first insulating layer and a second insulating layer sequentially stacked along a direction away from the substrate; and the forming the contact hole comprises:
sequentially etching the second insulating layer and the first insulating layer to form the contact hole penetrating to a surface of the substrate.

3. The method according to claim 1, wherein the insulating dielectric layer comprises a first insulating layer and a second insulating layer sequentially stacked along a direction away from the substrate; and the forming the contact hole comprises:
sequentially etching the second insulating layer, the first insulating layer, and the substrate to form the contact hole penetrating into the substrate.

4. The method according to claim 2, wherein an etching selectivity between the first insulating layer and the second insulating layer is controlled to form the contact hole shaped like an inverted wine cup.

5. The method according to claim 2, wherein the first hole segment is positioned in the first insulating layer, and the second hole segment being positioned in the second insulating layer.

6. The method according to claim 3, wherein a first part of the first hole segment is positioned in the substrate, a second part of the first hole segment being positioned in the first insulating layer, the second hole segment being positioned in the second insulating layer, and the first part comprising an arc-shaped bottom surface.

7. The method according to claim 1, wherein the forming the conductive plug comprises:
forming a metallic compound layer on a bottom surface of the contact hole;
covering a barrier layer on a hole wall of the contact hole and on a surface of the metallic compound layer; and
forming a metal filling portion on a surface of the barrier layer, the metal filling portion being configured to fill up the contact hole.

8. The method according to claim 7, wherein the forming the metallic compound layer comprises:
covering a metal layer on the hole wall and the bottom surface of the contact hole; and
annealing the substrate covered with the metal layer, such that the metal layer reacts with the substrate to form the metallic compound layer.

9. The method according to claim 7, wherein the forming the metallic compound layer comprises:
forming a semiconductor epitaxial layer on the bottom surface of the contact hole;
forming, in the contact hole, a metal layer at least covering the semiconductor epitaxial layer; and
annealing the semiconductor epitaxial layer covered with the metal layer, such that the metal layer reacts with the semiconductor epitaxial layer to form the metallic compound layer.

10. The method according to claim 9, wherein a thickness of the semiconductor epitaxial layer is 10-20 nm, and a thickness of the metal layer being 5-30 nm.

11. The method according to claim 7, wherein the forming the metal filling portion comprises:
covering a metal material on the surface of the barrier layer to form a seed layer; and
filling the metal material in the contact hole by means of an electroplating process to form the conductive plug.

12. The method according to claim 11, wherein a thickness of the seed layer is 2-20 nm.

13. A contact structure, comprising a conductive plug positioned on a substrate, the conductive plug comprising: a first conductive segment and a second conductive segment connected to each other, the second conductive segment being arranged on a side of the first conductive segment away from the substrate, wherein the conductive plug is shaped like an inverted wine cup, and a sectional dimension of the first conductive segment being greater than a sectional dimension of the second conductive segment.

14. The contact structure according to claim 13, wherein in a direction parallel to a surface of the substrate, a ratio of a maximum sectional dimension of the first conductive segment to a maximum sectional dimension of the second conductive segment is greater than or equal to 2.

15. The contact structure according to claim 13, wherein the conductive plug further comprises:
a metallic compound layer arranged between the substrate and the first conductive segment.

16. The contact structure according to claim 13, further comprising:
a barrier layer at least covering a periphery of the conductive plug.
